(19) United States
(12) Patent Application Publication
(10) Pub. No.: US 2007/0279846 A1
(43) Pub. Date: Dec. 6, 2007

(54) Motherboard with Illumination Device

(75) Inventor: Yen-Po Yu, Peitou (TW)

Correspondence Address: THOMAS, KAYDEN, HORSTEMEYER & RISLEY, LLP, 600 GALLERIA PARKWAY, STE 1500, ATLANTA, GA, 30339, US

(73) Assignee: ASUSTeK COMPUTER INC., Peitou (TW)

(21) Appl. No.: 11/757,716

(22) Filed: Jun. 4, 2007

Related U.S. Application Data
(60) Provisional application No. 60/811,015, filed on Jun. 5, 2006.

(51) Int. Cl. H05K 5/00

(52) U.S. Cl. 361/679

(57) ABSTRACT

A motherboard including a circuit board, a connecting device and an illumination device is provided. The connecting device and the illumination device are disposed on the circuit board, The illumination device includes at least one lighting element. The lighting element and the connecting device are disposed on the same side of the circuit board.

### CROSS-REFERENCE TO RELATED APPLICATION

This application claims the priority benefit of U.S. Provisional Application Ser. No. 60/811,015, filed Jun. 5, 2006, the full disclosures of which are incorporated herein by reference.

### BACKGROUND

1. Field of Invention

The present invention relates to a motherboard, and more particularly, to a motherboard with an illumination device.

2. Description of Related Art

Computers have become an indispensable tool for people. With knowledge about information technology, installing and inspecting the elements of a computer by users themselves has become increasingly common. However, due to the lack of illumination, inspecting accessories in the chassis is inconvenient. For example, users may need to connect peripheral devices with the connectors and the headers on motherboards when computers are assembled or maintained. However, recognizing the connectors and the headers in the chassis under insufficient illumination condition is not easy. In addition, users may need to recognize the marks printed adjacent to the connectors to identify them. However, most conventional computer systems do not have an illumination device in the chassis. Hence, users have to move the computer to a place with sufficient illumination or utilize a flashlight to illuminate the connectors, the headers and the marks. This is annoying and inconvenient for users.

Accordingly, it is required to provide a motherboard with an illumination device, which can provide illumination for users to recognize the connectors, the headers and the marks on the motherboard.

### SUMMARY

In an aspect of the present invention, a motherboard with an illumination device is provided. The illumination device can illuminate the connecting devices and/or the marks on the motherboard, thus enhancing the operating convenience for users.

In another aspect of the present invention, a motherboard with an illumination device is provided. The motherboard may include a switch to turn off the power transmission from a power source to electronic elements of the motherboard. Thus, illumination can be obtained without risk of damaging the electronic elements when users operate the connecting device.

In accordance with an embodiment of the present invention, a motherboard including a circuit board, a connecting device and an illumination device is provided. The connecting device and the illumination device are disposed on the circuit board. The illumination device includes at least one lighting element. The lighting element and the connecting device are disposed on the same side of the circuit board. Thus, the illumination device can illuminate the connecting devices and enhance the operating convenience for users.

In accordance with an embodiment of the present invention, a motherboard including a circuit board, a connecting device, a mark, an electronic element, an illumination device and a switch is provided. The connecting device, the mark, the electronic element, the illumination device and the switch are disposed on the circuit board. The illumination device includes at least one lighting element to illuminate the motherboard. The lighting element and the connecting device are disposed on the same side of the circuit board. The switch coupled with the electronic element and a power source to turn the electronic element on or off. Thus, illumination can be obtained without the risk of damaging the electronic elements when users operate the connecting device.

In accordance with an embodiment of the present invention, the switch is coupled with the electronic element, the illumination device and the power source. The switch connects either the electronic element or the illumination device with the power source electrically. Thus, the illumination devices not only illuminate the connecting device, but also indicate disconnections between the electronic element and the power source.

It is to be understood that both the foregoing general description and the following detailed description are by examples and are intended to provide further explanations of the invention as claimed.

### BRIEF DESCRIPTION OF THE DRAWINGS

These and other features, aspects and advantages of the invention will become apparent by reference to the following description and accompanying drawings, which are given by way of illustration only, and thus are not limitative of the invention, wherein:

FIG. 1 is a top view of a motherboard according to one preferred embodiment of this invention;

FIG. 1A illustrates an enlarged diagram of the region A in FIG. 1;

FIG. 2 is a block diagram of a motherboard according to one preferred embodiment of this invention; and

FIG. 3 is a block diagram of a motherboard according to another preferred embodiment of this invention.

### DESCRIPTION OF THE PREFERRED EMBODIMENTS

Connectors, headers and marks on a conventional motherboard are difficult to be recognized when the motherboard is installed in a chassis. In accordance with an embodiment of the present invention disclosed herein, a motherboard with an illumination device is provide, so as to provide sufficient illumination for users to recognize the connectors, the headers and the marks on the motherboard, thus enhancing the operating convenience for users.

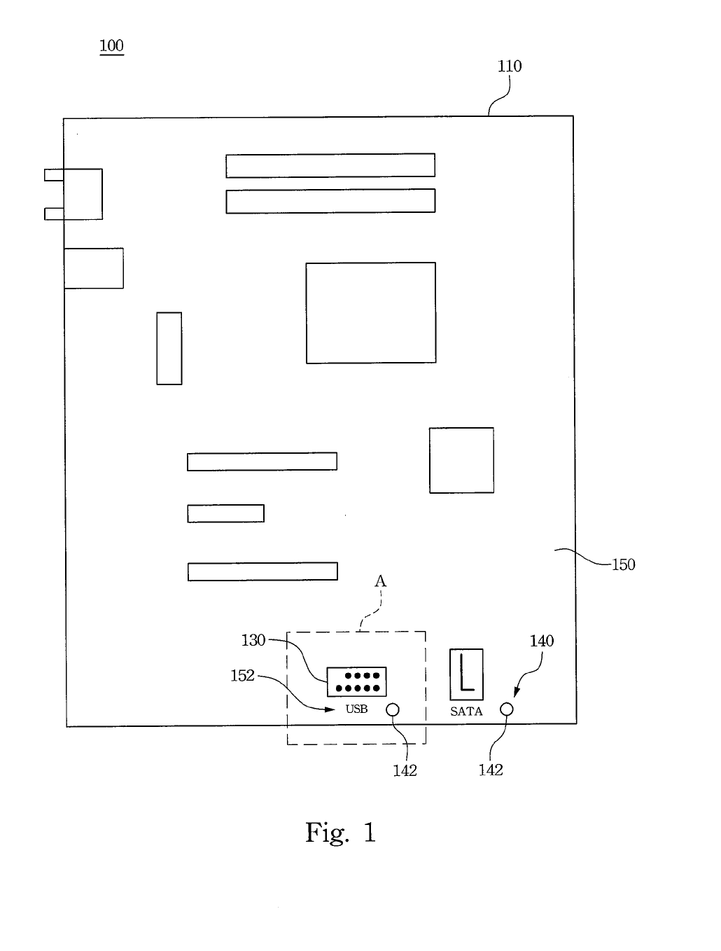

FIG. 1 is a top view of a motherboard according to one preferred embodiment of this invention. In FIG. 1, the motherboard 100 includes a circuit board 110, at least one connecting device 130 and an illumination device 140. The connecting device 130 disposed on the circuit board 110 may be a connector or a header to connect the motherboard 100 with other electronic devices. The illumination device 140 disposed on the circuit board 110 includes at least one lighting element 142. The lighting element 142 and the connecting device 130 are disposed on the same side 150 of the circuit board 110. Thus, the lighting element 142 can illuminate the motherboard 100 even when the motherboard 100 is installed in a chassis.

With continued reference to FIG. 1, the mark 152 printed adjacent to the connecting device 130 indicates the type or the function of the connecting device 130. For example, the connecting device 130 may be a Universal Serial Bus (USB) connector and the mark 152 is printed adjacent thereto. The lighting element 142 may be a light emitting diode or a luminescence device. Also, the lighting element 142 may be a fluorescence device, which can illuminate the motherboard 100 without electric power. With the lighting element 142, users can recognize the connecting device 130 and the mark 152 easily even when the motherboard 100 is installed in a chassis.

FIG. 1A illustrates an enlarged diagram of the region A in FIG. 1, the lighting element 142 can illuminate the connecting device 130 and/or the mark 152. The lighting element 142 may be a surface-mount light emitting diode (LED) or a side emitting surface-mount LED, which can illuminate the mark 152 preferably.

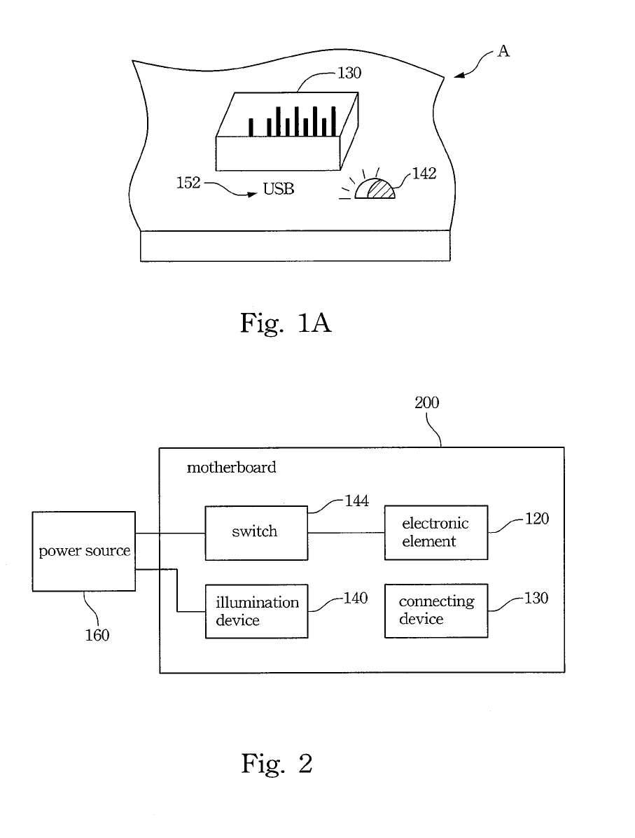

FIG. 2 is a block diagram of a motherboard according to one preferred embodiment of this invention. Referring to FIG. 2, the motherboard 200 includes at least one electronic element 120, at least one connecting device 130, an illumination device 140 and a switch 144. The motherboard 200 is electrically coupled with the power source 160, which can provide electric power to the illumination device 140 and the electronic element 120. The illumination device 140 is electrically connected with the power source 160 directly. The switch 144 is coupled with the electronic element 120 and the power source 160. Moreover, the switch 144 can turn the electronic element 120 on or off.

For example, the electronic element 120 may be a southbridge chipset and the power source 160 may be a standby power, which can provide electric power to the illumination device 140 and/or the electronic element 120 when the motherboard 200 is in a standby mode. In order to protect the electronic element 120 from being damaged when users operate the connecting device 130, the switch 144 can cut off the power transmission from the power source 160 to the electronic element 120. Thus, illumination can be obtained without the risk of damaging the electronic element 120 when users operate the connecting device 130.

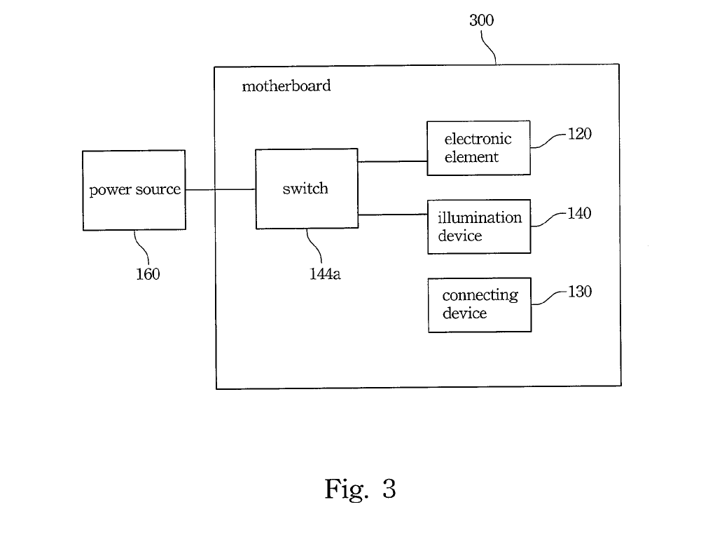

FIG. 3 is a block diagram of a motherboard according to another preferred embodiment of this invention. Referring to FIG. 3, the motherboard 300 includes at least one electronic element 120, at least one connecting device 130, an illumination device 140 and a switch 144a. The motherboard 300 is electrically coupled with the power source 160, which can provide electric power to the illumination device 140 and the electronic element 120 when the motherboard 200 is in a standby mode. The switch 144a is coupled with the electronic element 120, illumination device 140 and the power source 160. Moreover, the switch 144a can connect either the electronic element 120 or the illumination device 140 with the power source 160 electrically.

For example, the power source 160, which may be a standby power, can output electric power to the electronic element 120 when the motherboard 300 is in a standby mode. Users can change the load of the power source 160 from the electronic element 120 to the illumination device 140 when they operate the connecting device 130. In other words, the illumination device 140 can be electrically connected with the power source 160 while the electronic element 120 can be electrically isolated from the power source 160 by using the switch 144a. It is worth noting that the illumination devices 140 can illuminate the connecting device 130 and indicate disconnections between the electronic element 120 and the power source 160. Moreover, illumination can be obtained without risk of damaging the electronic element 120 when users operate the connecting device 130.

In accordance with an embodiment of the present invention disclosed herein, a motherboard with an illumination device is provided. The illumination device can illuminate the connecting devices and/or the marks on the motherboard, thus enhancing the operating convenience for users. Moreover, the motherboard may include a switch to turn off the power transmission from a power source to electronic elements of the motherboard. Thus, illumination can be obtained without risk of damaging the electronic elements when users operate the connecting device.

While the invention has been described by way of example and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A motherboard comprising:
a circuit board;
at least one connecting device, disposed on the circuit board; and
an illumination device disposed on the circuit board, including at least one lighting element to illuminate the motherboard;
wherein the lighting element and the connecting device are disposed on the same side of the circuit board.

2. A motherboard as recited in claim 1, wherein the lighting element is disposed adjacent to the connecting device.

3. A motherboard as recited in claim 1, further comprising at least one mark disposed on the circuit board and adjacent to the connecting device.

4. A motherboard as recited in claim 3, wherein the lighting element is disposed adjacent to the mark.

5. A motherboard as recited in claim 1, wherein the lighting element is a light emitting diode.

6. A motherboard as recited in claim 5, wherein the light emitting diode is a surface-mount light emitting diode.

7. A motherboard as recited in claim 5, wherein the light emitting diode is a side emitting surface-mount light emitting diode.

8. A motherboard as recited in claim 1, wherein the lighting element is a luminescence device.

9. A motherboard as recited in claim 1, wherein the lighting element is a fluorescence device.

10. A motherboard as recited in claim 1, further comprising at least one electronic element and a switch disposed thereon, wherein the switch is coupled with the electronic element and a power source to turn the electronic element on or off.

11. A motherboard as recited in claim 10, wherein the switch is coupled with the electronic element, the illumination device and the power source, and wherein the switch connects either the electronic element or the illumination device with the power source electrically.

12. A motherboard comprising:
a circuit board;
at least one connecting device, disposed on the circuit board;
at least one mark, disposed on the circuit board and adjacent to the connecting device;
at least one electronic element, disposed on the circuit board;
an illumination device disposed on the circuit board, including at least one light emitting diode to illuminate the motherboard, wherein the light emitting diode and the connecting device are disposed on the same side of the circuit board; and
a switch coupled with the electronic element and a power source to turn the electronic element on or off.

13. A motherboard as recited in claim 12, wherein the light emitting diode is a surface-mount light emitting diode.

14. A motherboard as recited in claim 12, wherein the light emitting diode is a side emitting surface-mount light emitting diode.

15. A motherboard as recited in claim 12, wherein the switch is coupled with the electronic element, the illumination device and the power source, and wherein the switch connects either the electronic element or the illumination device with the power source electrically.
